(19) United States
(12) Patent Application Publication
(10) Pub. No.: US 2008/0278346 A1
(43) Pub. Date: Nov. 13, 2008

(54) Single-Pin Multi-Bit Digital Circuit Configuration

(76) Inventors: Sabin A. Eftimie, Victoria (RO); Sorin S. Georgescu, San Jose, CA (US); Alexandra A. Epure, Bucharest (RO)

Correspondence Address: LAW OFFICE OF ANDREI D POPOVICI, P.C., 4020 MOORPARK AVE., SUITE101, SAN JOSE, CA, 95117, US

(21) Appl. No.: 11/747,435

(22) Filed: May 11, 2007

(51) Int. Cl. G08C 19/16; H03M 5/00

(52) U.S. Cl. 340/870.21

(57) ABSTRACT

According to some embodiments, a single-pin method of configuring a multi-bit state of a state machine of a circuit comprises: connecting a configuration resistor load having a configuration resistance to a single input pin of the integrated circuit; injecting a configuration current through the input pin and configuration resistor load; in response to injecting the current, generating a sequence of configuration signals indicative of a plurality of results of a plurality of comparisons of the configuration resistance to a plurality of predetermined thresholds, each result corresponding to a threshold; and configuring the multi-bit state of the state machine according to the sequence of configuration signals.

### BACKGROUND

This invention relates to systems and methods for configuring digital circuit settings, and in particular to systems and methods for configuring multi-bit digital circuit settings using a single external pin.

Some electronic system devices require configuring an internal setting (e.g. an address or operating mode) at device start-up. A multi-bit control word defining the setting may be communicated to the device by tying several input pins of the device to binary voltage values, e.g. ground or Vcc. Such an approach may not be practical for encoding large control words if the number of bits to be encoded exceeds the number of available external pins. In another approach, a serial data port or shared data bus may be used to control internal device settings using fewer external pins than the number of bits of the encoded data. Decoding data received over a serial port or shared data bus may add significant complexity to a device.

In U.S. Pat. No. 6,967,591, Dwelley et al. describe devices and methods for transmitting a multi-bit digital signal as a voltage signal via a single pin. The multi-bit digital signal is transmitted as a voltage signal substantially at one time, as opposed to serially. FIG. 1 is a diagram of a device 1100 described by Dwelley et al. An input voltage at an input pin 1110 is programmed by the value of two resistors 1130, 1140. Device 1100 may include other I/O pins 1120 for transmitting signals to or from device 1100. Resistors 1130, 1140 function as a voltage divider, providing a voltage that is a known fraction of Vcc. Dewey et al. describe using an analog-to-digital (A/D) converter to convert the voltage at the input pin into a digital value. For example, in a device using a 2-bit digital number as an input, 00 may correspond to an input voltage between 0% and 25% of the power-to-ground voltage, 01 to 25-50%, 10 to 50-75%, and 11 to 75-100%. A particular voltage value for the input pin may be chosen by appropriately choosing an appropriate ratio for the resistances of resistors 1130, 1140. The device configuration approach described by Dwelley et al. generally requires two or more resistors to define the input pin voltage.

### SUMMARY

According to one aspect, exemplary systems and methods described below allow configuring a multi-bit state of a circuit according to the resistance of a single configuration resistor connected to a single input pin of the circuit.

According to another aspect, a single-pin method of configuring a multi-bit state of a state machine of a circuit comprises: connecting a configuration resistor load having a configuration resistance to a single input pin of the integrated circuit; running a configuration current through the input pin and configuration resistor load; in response to running the current, generating a sequence of configuration signals indicative of a plurality of results of a plurality of comparisons of the configuration resistance to a plurality of predetermined thresholds, each result corresponding to a threshold; and configuring the multi-bit state of the state machine according to the sequence of configuration signals.

According to another aspect, a method comprises connecting a configuration resistor load having a configuration resistance to a single input pin of a circuit to run a configuration current through the input pin and configuration resistor load; and, in response to running the configuration current through the input pin and configuration resistor load, generating a multi-bit digital signal comprising a plurality of configuration signals indicative of the configuration resistance.

According to another aspect, a configurable digital system comprises a state machine; a configuration resistor load having a configuration resistance; and a state machine configuration circuit connected to the configuration resistor load over a single pin and connected to the state machine. The state machine configuration circuit is configured to run a configuration current through the input pin and configuration resistor load; in response to running the current through the input pin and configuration resistor load, generate a plurality of configuration signals indicative of the configuration resistance; and configure the multi-bit state of the state machine according to the plurality of configuration signals.

### BRIEF DESCRIPTION OF THE DRAWINGS

The foregoing aspects and advantages of the present invention will become better understood upon reading the following detailed description and upon reference to the drawings where:

FIG. 1 illustrates a prior art system for generating a multi-bit digital signal from a voltage signal on a single input pin.

FIG. 2-A shows a circuit configurable according to a current value determined by a single resistor load connected to an input pin of the circuit, according to some embodiments of the present invention.

FIG. 2-B is a more detailed diagram of the circuit of FIG. 2-A according to some embodiments of the present invention.

FIG. 3 shows a sequence of steps performed to store an exemplary 4-bit configuration word in a state machine configuration register according to some embodiments of the present invention.

FIG. 4 shows a diagram of a state machine according to some embodiments of the present invention.

FIG. 5 shows a set of waveforms for a state machine configuration cycle according to some embodiments of the present invention.

FIG. 6-A shows a variable resistor and associated digital resistor trimmer/decoder circuit according to some embodiments of the present invention.

FIG. 6-B shows another variable resistor and associated digital resistor trimmer/decoder circuit according to some embodiments of the present invention.

FIG. 7-A shows a resistor comparator circuit according to some embodiments of the present invention.

FIG. 7-B shows another resistor comparator circuit according to some embodiments of the present invention.

FIG. 7-C shows another resistor comparator circuit according to some embodiments of the present invention.

FIG. 8 shows a current comparator circuit according to some embodiments of the present invention.

FIG. 9 is a diagram of a circuit including a configuration resistor R1 connected in series with a variable reference resistor R2 according to some embodiments of the present invention.

FIG. 10 shows a current comparator circuit suitable for use in the circuit of FIG. 9 according to some embodiments of the present invention.

### DETAILED DESCRIPTION OF PREFERRED EMBODIMENTS

The following description illustrates the present invention by way of example and not necessarily by way of limitation. Any reference to an element is understood to refer to at least one element. A set of elements is understood to include one or more elements. A plurality of elements includes at least two elements. Any recited connection is understood to encompass a direct operative connection or an indirect operative connection through intermediary structure(s). Unless otherwise specified, the term “ground” refers to a low-fixed-voltage rail (Vₛₛ), which may be held at a zero voltage level. Unless otherwise specified, the statement that a current is injected or run through a pin and resistor load does not limit the current to a particular sign/direction.

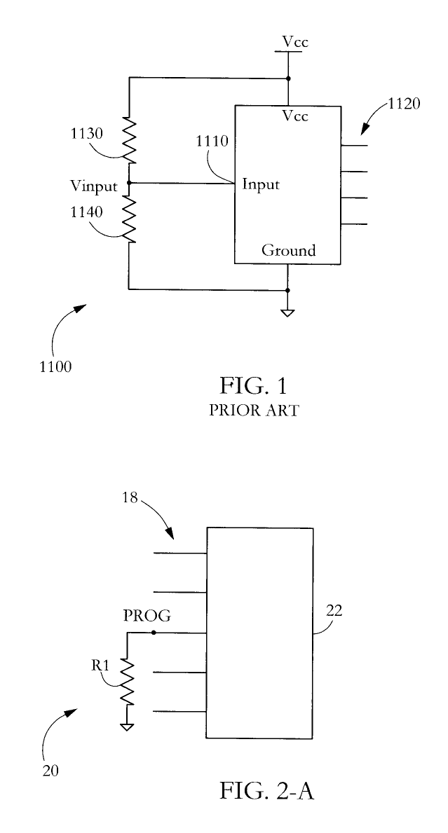

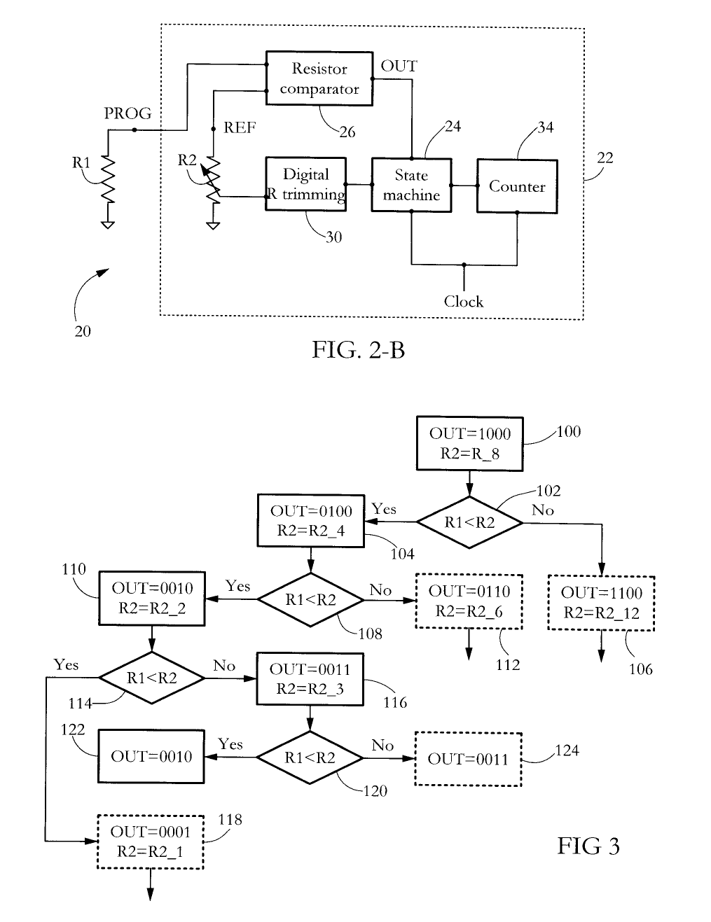

FIG. 2-A shows a diagram of a circuit 20 including a configurable digital circuit 22 and a single configuration resistor load R1 for configuring an internal state of circuit 22 according to some embodiments of the present invention. Preferably, resistor load R1 is formed by a single resistor. In some embodiments, resistor load R1 may include two or more resistors forming a network equivalent to a resistor. For simplicity of presentation and without disclaimer, the following discussion will focus on a resistor load formed by a single configuration resistor R1. Circuit 22 includes a plurality of pins 18 extending away from the package of circuit 22. Resistor R1 is connected between a fixed voltage (e.g. ground) and a configuration node PROG formed by one of the pins 18. Circuit 22 is used to apply an internal current or voltage bias to the node PROG, and to use one or more signals indicative of the current passing through the node PROG to configure a multi-bit internal state of circuit 22. No external bias is applied on the node PROG, so the signal collected internally on resistor R1 is only dependent on the value of R1 and the applied internal bias. The internal signal measured on R1 is used to generate a sequence of digital signals by sequentially comparing the resistance R1 of resistor R1 to a plurality of corresponding thresholds. Each threshold may correspond to a reference resistance, voltage, and/or current value, as described below.

FIG. 2-B is a diagram of circuit 20 showing an internal structure of circuit 22 according to some embodiments of the present invention. Circuit 22 includes a finite state machine 24, a resistor comparator 26, a digital resistor trimmer 30, a conversion step counter 34, and a variable reference resistor R2. State machine 24 and conversion step counter 34 are connected to a clock for receiving synchronization clock signals.

Resistor trimmer 30 sets the present value of reference resistor R2 according to control signals received from state machine 24. Conversion step counter 34 maintains one or more conversion step counts described below. State machine 24 includes a multi-bit configuration register configurable according to the value of a single configuration resistor R1 as described below. If the configuration register has N bits, N>1, state machine 24 has 2^{N} possible states. In some embodiments, state machine 24 passes through N out of its possible 2^{N} states as the internal state of state machine 24 is configured according to the resistance of resistor R1 as described below. Resistor comparator 26 has two inputs connected to resistor R1 at node PROG and to reference resistor R2 at an internal resistor reference node REF, and an output connected to state machine 24 at a node OUT. As the value of reference resistor R2 is varied in a sequence of N conversion steps (one conversion step per configuration register bit), resistor comparator 26 outputs to state machine 24 a sequence of binary signals each indicative of a relative magnitude of R1 and a present value of reference resistor R2 (e.g., for each value of R2, 1 if R1>R2 and 0 otherwise). State machine 24 is connected to resistor comparator 26, resistor trimmer 30, counter 34, and a synchronization clock signal source. State machine 24 receives one or more count signals from counter 24 and resistor comparison indicators from resistor comparator 26, generates a multi-bit configuration word according to the value of configuration resistor R1, and stores the configuration word in an internal register. State machine 24 also sends a control signal to resistor trimmer 30 at each conversion step, to set the value of reference resistor R2.

Table 1 shows an exemplary relationship between the values of a 2-bit (N=2) configuration word and corresponding R1 and R2 values according to some embodiments of the present invention. The resistor values in Table 1 are monotonically decreasing. The extreme possible values of the resistor R1 are zero (short) and very large (effectively infinity). Other potential values of R1 are spaced, equally or not, between the extreme values. For example, the other potential values of R1 may be uniformly spaced within a ten-fold range of resistance values (e.g. between 10 kOhms and 100 kOhms, or between 100 kOhms and 1 MOhm for lower-power applications). Each potential value taken by the reference resistor R2 is within a range defined by two consecutive values of R1, for example in the middle of the range. If the value of the resistor R1 is determined to be less than R2_{—}1, the configuration word logic value is set to 00. If the value of R1 is greater than R2_{—}3, the configuration word is set to 11. The configuration word is set to 01 if R1 is greater than R2_{—}1 and less than R2_{—}2, and to 10 if R1 is greater than R2_{—}2 and less than R2_{—}3.

TABLE 1

| Logic Value | R1 value | R2 value |
|---|---|---|
| 11 | R1_3~∞ | |
| | | R2_3 |
| 10 | R1_2 | |
| | | R2_2 |
| 01 | R1_1 | |
| | | R2_1 |
| 00 | R1_0~0 | |

FIG. 3 shows a sequence of steps performed to store an exemplary 4-bit configuration word 0010 (decimal 2) in state machine 24 according to some embodiments of the present invention. In FIG. 3, solid boxes denote configuration output values generated in the process of encoding the word 0010 (decimal 2), while dashed boxes denote alternative configuration output values which generated in the process of encoding other configuration words. For a 4-bit configuration word, R1 can take on values R1_{—}0 through R1_{—}15, and R2 can take on values R2_{—}1through R2_{—}15, with each value of R2 being situated between two consecutive values of R1. The word determination process includes a binary tree search proceeding through a sequence of comparisons of R1 to different R2 values, to determine the word bits from the most significant to the least. In an initial step 100, a configuration output (the logic value to be stored) is tentatively set to a middle value of 1000 (decimal 8), and the reference resistor R2 is set to a middle value R2_{—}8. In a step 102, R1 is compared to R2, and if R1<R2 the configuration output is tentatively set to 0100 (decimal 4), and R2 is set to R2_{—}4 (step 104). Step 102 effectively determines whether the most significant bit of the configuration word is 1 or 0, i.e. whether the configuration word set by R1 is less than eight. If R1>R2 (e.g. for an R1 resistance value encoding a configuration word other than 0010), the configuration output would be tentatively set to 1100 (decimal 12) and R2 set to R2_{—}12 (step 106), and the comparison process would continue to the next most significant bit in a manner analogous to the one described below. If a resistor comparison step 108 determines that R1<R2, the configuration output is tentatively set to 0010 (decimal 2) and R2 is set to R2_{—}2 (step 110). At this point in the process, it has been determined that the configuration word set by R1 is less than 0100 (decimal 4), and the remaining steps will determine whether the configuration word is 0, 1, 2 or 3. If step 108 determined that R1 is not less than R2, the configuration output would be tentatively set to 0110 (decimal 6) and R2 set to R2_{—}6 (step 112), and the comparison process would continue. In a comparison step 114 it is determined that R1 is not less than R2 (i.e. the configuration output is not less than decimal 2), and the configuration output is tentatively set to 0011 (decimal 3) and R2 is set to R2_{—}3 (step 116). The remaining potential values of the configuration word set by R1 are decimal 2 (0010) and 3 (0011). If step 114 determined that R1<R2, the configuration output would be set to 0001 (decimal 1) (step 118) and the comparison process would continue. In a comparison step 120 it is determined that R1<R2 (i.e. the configuration output is less than decimal 3), and in a step 122 the configuration output is set to 0010 (decimal 2). If step 120 determined that R1 is not less than R2, the configuration output would be set to 0011 (decimal 3) (step 124).

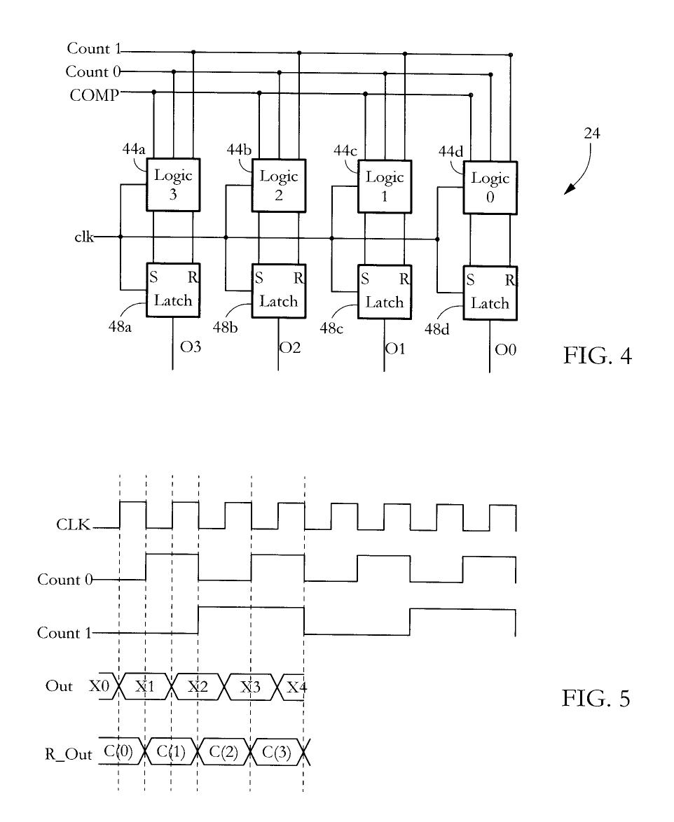

FIG. 4 shows a diagram of a state machine 24 suited for storing a 4-bit configuration word, while FIG. 5 shows a set of signal waveforms corresponding to a configuration cycle of state machine 24 according to some embodiments of the present invention. As shown in FIG. 4, state machine 24 includes four logic units 44a-d connected to four corresponding gated SR latches 48a-d. Each logic unit 44a-d controls a corresponding latch 48a-d. The four latch outputs O3-O0 represent the configuration word stored by latches 48a-d. The four latch outputs O3-O0 also serve as inputs for resistor trimmer 30 (FIG. 2-B) during word decoding/configuration sequences such as the sequence illustrated in FIG. 3, thus setting the value of variable resistor R2. In some embodiments, latches 48a-d may be replaced or connected to one or more registers for storing configuration word(s).

Each logic unit 44a-d has four one-bit inputs: a resistor comparator result input COMP for receiving a result of a resistor comparison from resistor comparator 26 (FIG. 2-B), two count inputs Count0 and Count1, for receiving two count signals from counter 34 (FIG. 2-B), and a synchronization clock input clk. FIG. 5 shows waveforms for an exemplary clock signal, Count0 and Count1 count signals, latch output signal (conversion) cycles X0-4 and resistor comparator output signal cycles C(O)- C(3), wherein C(O)- C(3) are abbreviated notations for COMP(0)- COMP(3). The resistor comparator signals C(O)- C(3) represent output signals generated by resistor comparator 26 (FIG. 2-B). The latch output signals X0-4 represent the output of state machine 24 and input of digital resistor trimmer 30 (FIG. 2-B). As shown in FIG. 5, the clock signal sets the outputs of latches 48a-d on rising clock edges, while the resistor comparator signal changes values on falling clock edges.

Table 2 shows exemplary values taken by the latch outputs O0-O3 (FIG. 4) for each conversion cycle X0-4.

TABLE 2

| | O3 | O2 | O1 | O0 |
|---|---|---|---|---|
| X0 | 1 | 0 | 0 | 0 |
| X1 | COMP(0) | 1 | 0 | 0 |
| X2 | COMP(0) | COMP(1) | 1 | 0 |
| X3 | COMP(0) | COMP(1) | COMP(2) | 1 |
| X4 | COMP(0) | COMP(1) | COMP(2) | COMP(3) |

As Table 2 shows, the latch outputs are set sequentially, starting with the most significant bit (MSB) O3 and ending with the least significant bit O0. Following the last conversion cycle, each latch output O0-O3 reflects a corresponding resistor comparison performed by resistor comparator 26. Initially, the latch outputs O3-O0 start out with the values (1000), which set the internal resistor R2 (FIG. 1) to a middle value R2_{—}8 as described above. At the first rising clock edge delimiting the conversion cycle X1 (FIG. 5), the MSB output O3 is set according to a resistor comparator signal value COMP(0). The MSB output O3 then remains unchanged for the remainder of the conversion process. The value of variable resistor R2 for a subsequent comparison is set to R2_{—}4 (binary 0100) or R2_{—}12 (binary 1100), depending on whether COMP(0) is 0 or 1.

The output O₂ has a value of 1 during the X1 conversion cycle, and is set to a resistor comparator signal value COMP(1) during the conversion cycle X2. The resistor comparator signal value COMP(1) reflects a comparison of the configuration resistor R1 to the variable resistor value R2_{—}4 (for COMP(0)=0) or R2_{—}12 (for COMP(0)=1). The output O₂ then remains unchanged during subsequent conversion cycles X3-4.

The output O1 has a value of 0 during the X1 cycle and 1 during the X2 cycle. During the X3 conversion cycle, the output O1 is set according to a resistor comparator signal value COMP(2), and remains unchanged thereafter. The resistor comparator signal value COMP(2) reflects a comparison of the configuration resistor R1 to R2_{—}2 (0010), R2_{—}6 (0110), R2_{—}10 (1010), or R2_{—}14 (1110), depending on the values of COMP(0) and COMP(1).

The output O0 has a value of 0 during the X1 and X2 cycles and 1 during the X3 cycle. During the X4 conversion cycle, the output O0 is set according to a resistor comparator signal value COMP(3). The resistor comparator signal value COMP(3) reflects a comparison of the configuration resistor R1 to R2_{—}1 (0001), R2_{—}3 (0011), R2_{—}5 (0101), R2_{—}7 (0111), R2_{—}9 (1001), R2_{—}11 (1011), R2_{—}13 (1101), or R2_{—}15 (1111), depending on the values of COMP(0), COMP(1) and COMP(2).

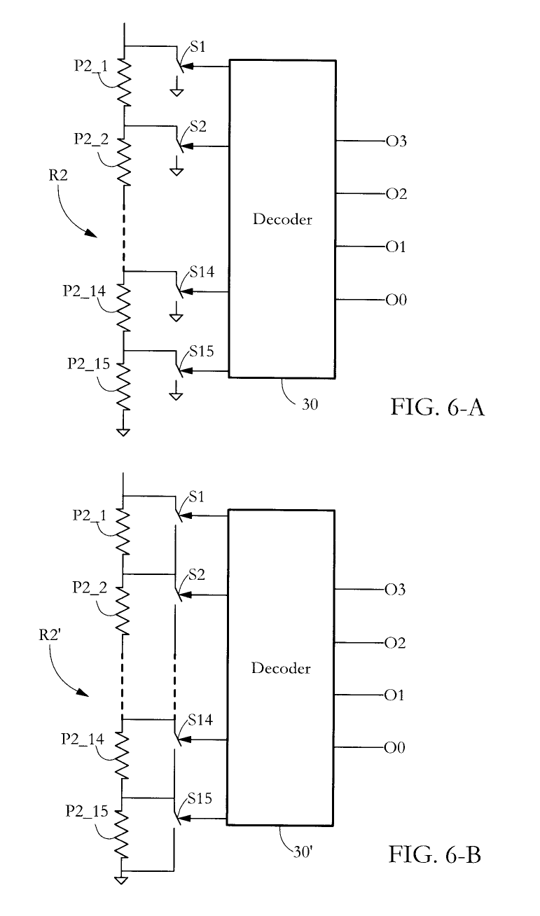

FIG. 6-A shows a variable resistor R2 and associated digital resistor trimmer/decoder circuit 30 according to some embodiments of the present invention. Resistor R2 includes a string of resistive elements P2_1-15 connected in series between an input of resistor comparator 26 (FIG. 2-B) and ground. Decoder 30 is capable of selectively shorting a string of resistive elements P2_15, j=1 . . . 15, to ground. Decoder 30 controls a plurality of switches S1-S15, wherein each switch is connected between the higher-voltage node of a corresponding resistive element P2_1-15 and ground. Closing a switch Sn (n−1 . . . 15) shorts its corresponding node to ground, leaving only the series of resistive elements P2_j, j<n, within the variable resistor R2 and thus controlling the value of variable resistor R2. For example, closing the switch S1 brings the value of R2 to zero, while leaving all switches S1-15 open brings the value of R2 to its maximal value, which is the sum of the resistances of the resistive elements P2_1-15. Switches S1-15 are controlled by decoder 30 according to input signals O0-O3 received from state machine 24 (FIG. 4).

FIG. 6-B shows a variable resistor R2′ and associated digital resistor trimmer/decoder circuit 30′ according to some embodiments of the present invention. Decoder 30′ is capable of selectively shorting one or more individual resistive elements P2_1-15 of resistor R2′. Decoder 30′ controls a plurality of switches S1-15′, wherein each switch is connected across (in parallel with) a corresponding resistive element P2_1-15. Closing a switch Sn provides a shorted path around its corresponding resistive element P2_n, effectively taking resistive element P2_n out of variable resistor R2′ and thus controlling the value of variable resistor R2′.

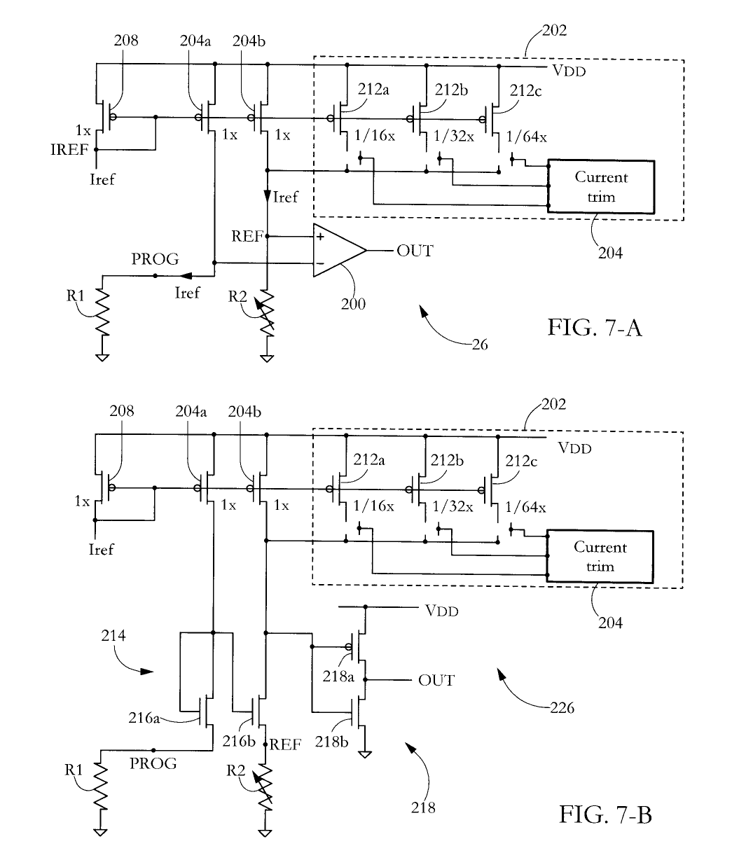

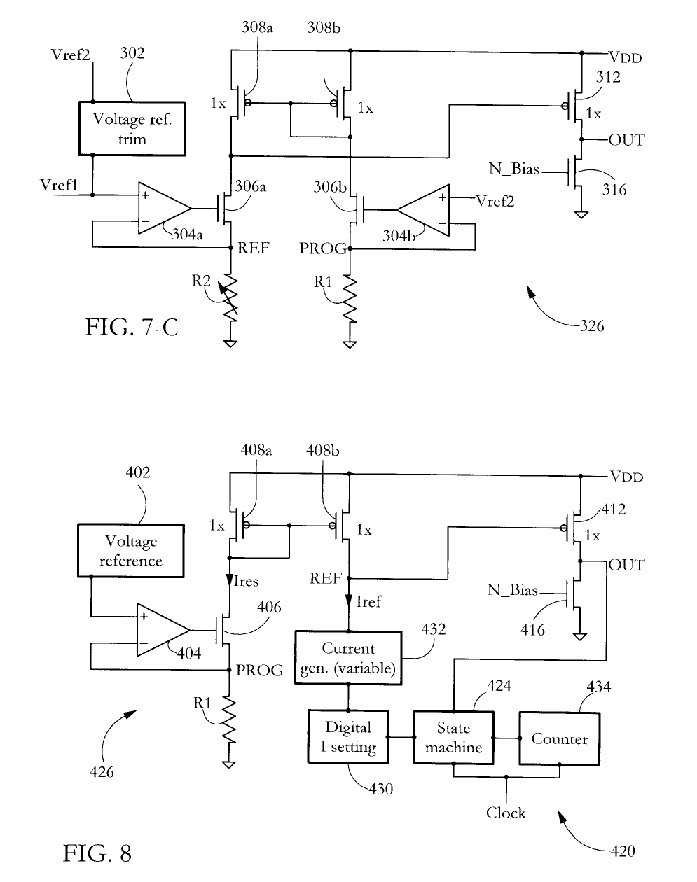

FIG. 7-A shows a resistor comparator 26 according to some embodiments of the present invention. Resistor comparator 26 generates an output signal having a logic value of one if R1<R2 and a logic value of zero if R1>R2. A differential amplifier 200 has its inputs PROG and REF connected to resistors R1 and R2, respectively, and an output OUT connected to state machine 24 (FIG. 2-B). The PROG and REF nodes are connected to a current mirror including identical (1×) p-type transistors 204a-b whose gates are commonly connected to a reference current node IREF. Reference current node IREF is connected to a 1× p-type current reference transistor 208 whose gate is also connected to the node IREF. The node IREF is connected to a constant current source which sets the current through node IREF to a reference value Iref. The current mirror circuit formed by transistors 204a-b and 208 sets the currents through nodes PROG and REF equal to the reference current Iref passing through node IREF. The voltages at the nodes PROG and REF are proportional to the reference current Iref passing through each nodes PROG and REF multiplied by the resistances of resistors R1 and R2, respectively. Consequently, the output voltage at node OUT is low (logic zero) when R1>R2 and high (logic one) when R1<R2.

A digital resistivity spread compensation unit 202 is connected to the IREF bias node. Digital spread compensation unit 202 is used to reduce the resistivity spread of variable resistors R2 resulting from a manufacturing process. A batch of integrated circuits may include variable resistors R2 with a distribution of resistances. The resistance properties of variable resistors R2 are evaluated in a calibration procedure performed during a manufacturing process. Resistivity spread compensation unit 202 is set according to the results of the calibration process to introduce additional resistance so as to yield desired, calibrated resistance properties for an equivalent circuit including variable resistor R2. Digital resistivity spread compensation unit 202 may be thought of as forming part of variable resistor R2, or part of a variable resistor including resistor R2 and digital resistivity spread compensation unit 202.

As shown in FIG. 7-A, resistivity spread compensation unit 202 includes three PMOS mirror transistors 212a-c connected between V_{DD} and the REF node under the control of a current trimming unit 204. Transistors 212a-c have 1/16×, 1/32×, and 1/16× area ratios, respectively, relative to the 1× areas of the rest of the transistors shown in FIG. 7-A. None, one or more of transistors 212a-c may be connected to the node REF during manufacture, according to the results of a calibration measurement performed for variable resistor R2, so as to yield a desired resistance value for the overall variable resistance presented by variable resistor R2 and resistivity spread compensation unit 202. Connecting transistors 212a-c to the node REF has an effect equivalent to introducing additional resistance(s) proportional to the transistor area(s) connected at node REF. In some embodiments, resistivity spread compensation unit 202 may allow a substantial reduction in the resistivity spread of variable resistors R2, for example from about 6% in the absence of resistivity spread compensation unit 202 to a value of about 1.5% in its presence. In some embodiments, if a higher precision is desired, a resistivity spread compensation unit may include higher numbers of transistors.

FIG. 7-B shows a resistor comparator circuit 226 according to some embodiments of the present invention. Comparator circuit 226 includes p-type transistors 204a-b, 208 and resistivity spread compensation unit 202 connected as described above. While resistor comparator circuit 26 (FIG. 7-A) used differential amplifier 200 to compare the voltages at the PROG and REF nodes, resistor comparator circuit 226 (FIG. 7-B) includes a current comparator circuit 214 for comparing the current flows through the PROG and REF nodes. Current comparator circuit 214 includes two n-type transistors 216a-b connecting the PROG and REF nodes to the drains of transistors 204a-b, respectively. The gates of transistors 216a-b are commonly connected to the drain of transistor 204a. The drain of transistor 216b forms the input of an inverter 218, whose output node OUT forms the output of resistor comparator circuit 226. Inverter 218 includes a p-type transistor 218a and an n-type transistor 218b connected in series between V_{DD} and ground, with the gates of transistors 218a-b commonly connected to the drain of transistor 216b. The commonly-connected drains of transistors 218a-b form the output node OUT. If R1=R2, identical currents flow through the REF and PROG nodes, and the nodes REF and PROG have identical voltages. If R1>R2, the current through resistor R1 is lower than the current through resistor R2, the drain of transistor 216b is driven low, and the inverter output OUT is driven high. If R1<R2, the current through resistor R1 is higher than the current through resistor R2, the drain of transistor 216b is driven high, and the output OUT is low.

FIG. 7-C shows a resistor comparator circuit 326 according to some embodiments of the present invention. Resistor comparator circuit 326 uses voltage trimming rather than current trimming to compensate for deviations of the resistance values of variable resistor R2 from pre-determined values. Two parallel current branches between V_{DD} and ground include p-type transistors 308a-b, n-type transistors 306a-b, and resistors R2 and R1, respectively. The gates of p-type transistors 308a-b are commonly connected to the drains of transistors 308b and 306b. The gates of n-type transistors 306a-b are connected to the outputs of two differential amplifiers 304a-b, respectively. One input of amplifier 304a is held at reference voltage Vref1 supplied by a voltage reference trim unit 302, while the other input is formed by variable resistor reference node REF. One input of amplifier 304b is held at a reference voltage Vref2 supplied by voltage reference trim unit 302, while the other input if formed by configuration node PROG.

A third current branch between V_{DD} and ground includes a p-type transistor 312 and an n-type transistor 316 connected in series. The commonly connected drains of p-type transistor 312 and n-type transistor 316 form an output OUT of resistor comparator circuit 326. The gate of p-type transistor 312 is connected to the drains of transistors 306a, 308a, while the gate of n-type transistor 316 is connected to a voltage bias source supplying a voltage N_bias. The voltage N_bias may be chosen to yield equal currents through transistors 308a-b and 312 when R1=R2.

During the operation of resistor comparator circuit 326, differential amplifiers 304a-b force the nodes REF and PROG to be equal to the voltages Vref1 and Vref2, respectively. Voltage reference trim unit 302 may be used to trim reference voltage Vref2 to compensate for any spread in the resistivity of variable resistor R2. Under ideal conditions, if the resistance R2 is set precisely, the two reference voltages Vref1 and Vref2 are equal. In practice, the reference voltage Vref2 may be chosen to compensate for any deviation of the resistance value of variable resistor R2 from pre-determined values. Effectively, the reference voltage Vref2 may serve the role described above for resistivity spread compensation unit 202 (FIG. 7-A), so that the circuit output switches states at pre-determined desired values of the resistance R1, even when these desired values are slightly different from the resistance values of variable resistor R2.

The values of the two resistors R1 and R2 determine the current value through the corresponding nodes PROG and REF. The difference in current values between the nodes PROG and REF determines the logic level at the output OUT: if the current through node PROG is lower than the current through node REF (i.e., for Vref1=Vref2, if R1>R2), the output voltage at the node OUT has a high value. The output voltage has a low value otherwise.

FIG. 8 shows a configurable circuit 420 including a current comparator circuit 426 according to some embodiments of the present invention. As above, an external configuration pin, illustrated as a configuration node PROG in FIG. 8, is used to configure a multi-bit internal state of a finite state machine 424. A configuration resistor R1 is connected between ground and the node PROG. Circuit 420 further includes a digital current setting unit 430, a variable current generator (source) 432 under the control of digital current setting unit 430, and a conversion step counter 434. State machine 424 and conversion step counter 434 are connected to a clock for receiving clock signals.

The configuration node PROG is connected to ground through configuration resistor R1 and to V_{DD} through a p-type transistor 408a and an n-type transistor 406 connected in series. An internal current reference node REF is connected to V_{DD} through a p-type transistor 408b. The gates of transistors 408a-b are commonly connected to the drain of n-type transistor 406, while the source of n-type transistor 406 is connected to the configuration node PROG. The gate of n-type transistor 406 is connected to the output of a differential amplifier 404. The inputs of differential amplifier 404 are connected to a voltage reference unit 402 and to the configuration node PROG, respectively.

A current branch between V_{DD} and ground includes a p-type transistor 412 and an n-type transistor 416 connected in series. The commonly connected drains of p-type transistor 412 and n-type transistor 416 form an output OUT of resistor comparator circuit 426. The gate of p-type transistor 412 is connected to the variable resistor reference node REF, while the gate of n-type transistor 416 is connected to a voltage bias source supplying a bias voltage N_bias.

Current comparator circuit 426 employs variable current generator 432 instead of a variable resistor R2 to perform a comparison of a current Iref through current reference node REF to a current Ires through a configuration node PROG. Under the control of digital current setting unit 430, variable current generator 432 sets the current through the internal current reference node REF sequentially to a set of predetermined values. The reference current values may be chosen according to the possible values taken on by the current through the configuration node PROG (the current through resistor R1) as shown above in Table 1, with the values of R1 and R2 in Table 1 replaced by the currents through nodes PROG and REF. When Iref>Ires, the output OUT goes high, and when Iref<Ires, the output OUT goes low. The circuit of FIG. 8 effectively allows a comparison of the resistance of configuration resistor R1 to a sequence of threshold values each defined by a corresponding value of the reference current Iref.

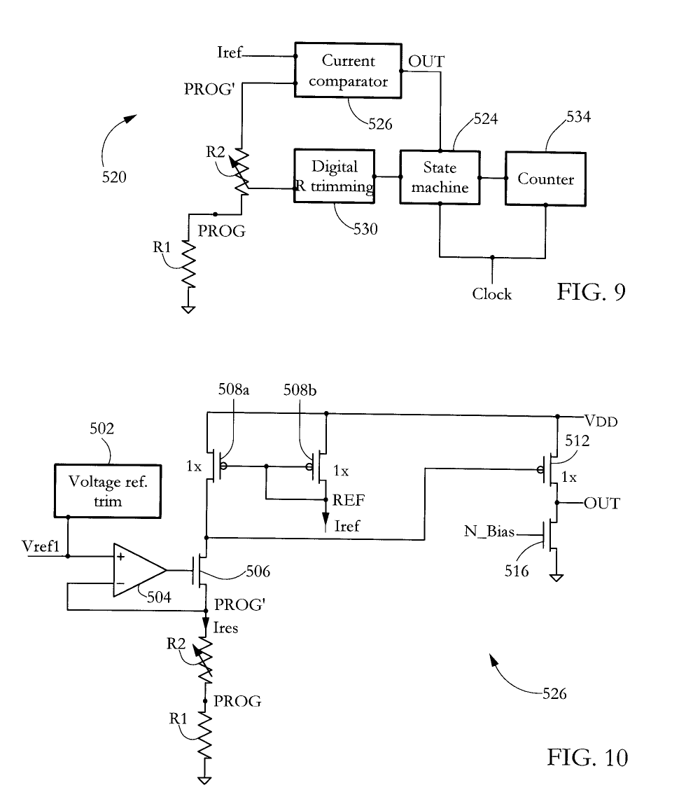

FIG. 9 is a diagram of a circuit 520 including a configuration resistor R1 connected in series with a variable reference resistor R2 according to some embodiments of the present invention. Circuit 520 includes a state machine 524, counter 534, and digital resistor trimmer 530 connected as described above. A current comparator 526 has an output connected to state machine 524, a first input connected to a fixed reference current source generating a fixed reference current Iref, and a second input connected to ground through variable resistor R2 and configuration resistor R1 connected in series.

FIG. 10 is a diagram of current comparator circuit 526 according to some embodiments of the present invention. An external configuration node PROG is formed by an external pin of circuit 520, and is connected to ground through configuration register R1. A variable reference resistor R2 is connected between the external configuration node PROG and an internal configuration node PROG′. The internal configuration node PROG′ is connected to V_{DD} through a p-type transistor 508a and an n-type transistor 506 connected in series. An internal current reference node REF is connected to V_{DD} through a p-type transistor 508b. A current Iref flowing through reference node REF serves as a reference for evaluating whether configuration resistor R1 is higher or lower than a set of predetermined thresholds. The gates of transistors 508a-b are commonly connected to the REF node. The drains of n-type transistor 506 and p-type transistor 508a are commonly connected. The gate of n-type transistor 506 is connected to the output of a differential amplifier 504. The inputs of differential amplifier 504 are connected to a voltage reference trim unit 502 and to the configuration node PROG′, respectively.

A current branch between V_{DD} and ground includes a p-type transistor 512 and an n-type transistor 516 connected in series. The commonly connected drains of p-type transistor 512 and n-type transistor 516 form an output OUT of current comparator circuit 526. The gate of p-type transistor 512 is connected to drains of transistors 506, 508a, while the gate of n-type transistor 516 is connected to a voltage bias source supplying a voltage N_bias.

The output voltage at node OUT is determined by a relationship between the reference current Iref and a current Ires passing through resistors R1 and R2. When Iref>Ires, the output OUT goes high, and when Iref<Iref, the output OUT goes low. In turn, the value of Ires is determined by the total resistance R1+R2. The fixed reference current Iref is sequentially compared to the current Ires for multiple values of R2, and the comparison results are used to configure state machine 524 as described above.

Exemplary embodiments described above allow using a single configuration resistor connected to a single input pin of configurable circuit to set a multi-bit internal state of the circuit. Using a single configuration resistor allows simplifying the steps performed by an end user to connect the circuit for a configuration/initialization process. A current flow through the input pin and configuration resistor to ground depends on the resistance of the configuration resistor. The current flow through the input pin and configuration resistor is used to effectively determine the configuration resistance value and to set the multi-bit internal state according to the configuration resistor value. In some embodiments, an indicator of the relative value of the configuration resistance may be determined by comparing a reference voltage or current to a corresponding voltage or current indicative of the configuration resistance. A resistivity spread compensation unit using voltage or current trimming may be used, in accordance with the results of calibration measurements, to compensate for deviations in the resistive properties of a variable resistor used to generate a reference voltage or current in some embodiments of the present invention. One or more of the various circuit configurations shown in FIGS. 7-A-C through FIG. 10 may be selected by a system designer according to desired circuit properties and/or available circuit resources. For example, the exemplary configuration of FIG. 7-C may be of particular interest in circuits in which a reference voltage source is used for functionality external to the configuration circuit described above. Similarly, the exemplary configuration of FIGS. 9-10 may be used in a circuit which uses a reference current source for a circuit section outside the configuration circuit described above.

It will be clear to one skilled in the art that the above embodiments may be altered in many ways without departing from the scope of the invention. For example, in some embodiments multiple comparison circuits may be employed to compare the configuration resistance value simultaneously (rather than sequentially) to a plurality of thresholds (e.g. a variable resistor R2 or variable reference current source as described above may be replaced by multiple comparison circuits each corresponding to one of the potential values of the variable resistor R2 or variable reference current source. In some embodiments, a multi-bit signal generated as described above may be provided as an input to a combinational circuit that does not include a register, rather than to a state machine. Accordingly, the scope of the invention should be determined by the following claims and their legal equivalents.

What is claimed is:

1. A single-pin method of configuring a multi-bit state of a state machine of a circuit, comprising:
connecting a configuration resistor load having a configuration resistance to a single input pin of the circuit;
running a configuration current through the input pin and configuration resistor load;
in response to running the current, generating a sequence of configuration signals indicative of a plurality of results of a corresponding plurality of comparisons of the configuration resistance to a plurality of predetermined thresholds, each result corresponding to a threshold; and
configuring the multi-bit state of the state machine according to the sequence of configuration signals.

2. The method of claim 1, further comprising directly connecting a first terminal of the configuration resistor load to ground, and a second terminal of the configuration resistor load to the input pin.

3. The method of claim 1, further comprising sequentially setting a resistance of a variable resistor load to a plurality of resistance levels each defining one of the predetermined thresholds.

4. The method of claim 3, wherein the variable resistor load is connected in series with the configuration resistor load.

5. The method of claim 3, wherein the variable resistor load is connected between ground and a reference node, and wherein the configuration resistor load is connected between ground and the input pin.

6. The method of claim 3, further comprising running predetermined currents through the configuration resistor load and the variable resistor load, and performing a voltage drop comparison between the configuration resistor load and the variable resistor load for each resistance level to generate the sequence of configuration signals.

7. The method of claim 3, wherein the predetermined currents are substantially identical.

8. The method of claim 3, further comprising applying predetermined voltages across the configuration resistor load and the variable resistor load, and performing a current comparison between the configuration resistor load and the variable resistor load for each resistance level to generate the sequence of configuration signals

9. The method of claim 8, wherein the predetermined voltages are substantially identical.

10. The method of claim 3, further comprising compensating for a deviation of a resistance of the variable resistor load from a preset target value according to a result of a calibration measurement performed on the variable resistor load.

11. The method of claim 10, wherein compensating for the deviation comprises trimming a current supplied to the variable resistor load according to the calibration measurement.

12. The method of claim 10, wherein compensating for the deviation comprises trimming a voltage supplied to the variable resistor load according to the calibration measurement.

13. The method of claim 1, further comprising comparing the configuration current to a plurality of reference current levels, wherein each configuration signal is an indicator of a result of a comparison between the configuration current and a reference current level.

14. The method of claim 1, further comprising sequentially setting a reference current generated by a variable reference current source to a plurality of reference current levels each defining one of the predetermined thresholds.

15. The method of claim 1, wherein the plurality of predetermined thresholds define a plurality of corresponding non-overlapping configuration resistance subranges of a resistance range, wherein the sequence of configuration signals identifies a selected subrange encompassing the configuration resistance.

16. The method of claim 1, wherein the configuration resistor load consists of a single resistor.

17. A method comprising:
connecting a configuration resistor load having a configuration resistance to a single input pin of a circuit to run a configuration current through the input pin and configuration resistor load; and
in response to running the configuration current through the input pin and configuration resistor load, generating a multi-bit digital signal comprising a plurality of configuration signals indicative of the configuration resistance.

18. The method of claim 17, further comprising configuring a multi-bit state of a state machine of the circuit according to the plurality of configuration signals.

19. The method of claim 17, further comprising directly connecting a first terminal of the configuration resistor load to ground, and a second terminal of the configuration resistor load to the input pin.

20. The method of claim 17, further comprising sequentially setting a resistance of a variable resistor load to a plurality of resistance levels, and generating the plurality of configuration signals by comparing a resistance of the configuration resistance load to the plurality of resistance levels.

21. The method of claim 20, wherein the variable resistor load is connected in series with the configuration resistor load.

22. The method of claim 20, wherein the variable resistor load is connected between ground and a reference node, and wherein the configuration resistor load is connected between ground and the input pin.

23. The method of claim 20, further comprising running predetermined currents through the configuration resistor load and the variable resistor load, and performing a voltage drop comparison between the configuration resistor load and the variable resistor load for each resistance level to generate the plurality of configuration signals.

24. The method of claim 23, wherein the predetermined currents are substantially identical.

25. The method of claim 20, further comprising applying predetermined voltages across the configuration resistor load and the variable resistor load, and performing a current comparison between the configuration resistor load and the variable resistor load for each resistance level to generate the plurality of configuration signals

26. The method of claim 25, wherein the predetermined voltages are substantially identical.

27. The method of claim 20, further comprising compensating for a deviation of a resistance of the variable resistor load from a preset target value according to a result of a calibration measurement performed on the variable resistor load.

28. The method of claim 27, wherein compensating for the deviation comprises trimming a current supplied to the variable resistor load according to the calibration measurement.

29. The method of claim 27, wherein compensating for the deviation comprises trimming a voltage supplied to the variable resistor load according to the calibration measurement.

30. The method of claim 17, further comprising comparing the configuration current to a plurality of reference current levels, wherein each configuration signal is an indicator of a result of a comparison between the configuration current and a reference current level.

31. The method of claim 17, further comprising sequentially setting a reference current generated by a variable reference current source to a plurality of reference current levels, wherein each configuration signal is an indicator of a result of a comparison between the configuration current and a reference current level.

32. The method of claim 17, wherein the configuration resistor load consists of a single resistor.

33. A configurable digital system comprising:
a state machine;
a configuration resistor load having a configuration resistance; and
a state machine configuration circuit connected to the configuration resistor load over a single pin and connected to the state machine, the state machine configuration circuit being configured to
run a configuration current through the input pin and configuration resistor load;
in response to running the current through the input pin and configuration resistor load, generate a plurality of configuration signals indicative of the configuration resistance; and
configure the multi-bit state of the state machine according to the plurality of configuration signals.

34. The system of claim 33, wherein a first terminal of the configuration resistor load is connected directly to ground, and a second terminal of the configuration resistor load is connected directly to the input pin.

35. The system of claim 33, wherein the state machine configuration circuit further comprises a variable resistor load, and wherein the state machine configuration circuit is configured to generate the plurality of configuration signals by comparing a resistance of the configuration resistance load to a plurality of resistance levels of the variable resistor load.

36. The system of claim 35, wherein the variable resistor load is connected in series with the configuration resistor load.

37. The system of claim 35, wherein the variable resistor load is connected between ground and a reference node, and wherein the configuration resistor load is connected between ground and the input pin.

38. The system of claim 35, wherein the state machine configuration circuit is configured to run predetermined currents through the configuration resistor load and the variable resistor load, and perform a voltage drop comparison between the configuration resistor load and the variable resistor load for each resistance level to generate the plurality of configuration signals.

39. The system of claim 38, wherein the predetermined currents are substantially identical.

40. The system of claim 35, wherein the state machine configuration circuit is configured to apply predetermined voltages across the configuration resistor load and the variable resistor load, and perform a current comparison between the configuration resistor load and the variable resistor load for each resistance level to generate the plurality of configuration signals

41. The system of claim 40, wherein the predetermined voltages are substantially identical.

42. The system of claim 35, wherein the state machine configuration circuit further comprises a resistivity spread compensation circuit connected to the variable resistor load and configured to compensate for a deviation of a resistance of the variable resistor load from a preset target value according to a result of a calibration measurement performed on the variable resistor load.

43. The system of claim 42, wherein the resistivity spread compensation unit comprises a current trimming circuit configured to trim a current supplied to the variable resistor load according to the calibration measurement.

44. The system of claim 42, wherein the resistivity spread compensation unit comprises a voltage trimming circuit configured to trim a voltage supplied to the variable resistor load according to the calibration measurement.

45. The system of claim 33, wherein the state machine configuration circuit is configured to compare the configuration current to a plurality of reference current levels, wherein each configuration signal is an indicator of a result of a comparison between the configuration current and a reference current level.

46. The system of claim 33, wherein the state machine configuration circuit further comprises a variable reference current source, wherein the state machine configuration circuit is configured to sequentially set a reference current generated by the variable reference current source to a plurality of reference current levels, and wherein each configuration signal is an indicator of a result of a comparison between the configuration current and a reference current level.

47. The system of claim 33, wherein the configuration resistor load consists of a single resistor.

48. A configurable digital system comprising:
a configuration resistor load having a configuration resistance and connected to a single input pin of a circuit
means for running a configuration current through the input pin and configuration resistor load;
means for generating a plurality of configuration signals indicative of the configuration resistance in response to running the current through the input pin and configuration resistor load; and
means for configuring a multi-bit state of a state machine of the circuit according to the plurality of configuration signals.
